(19) United States
(12) Patent Application Publication
(10) Pub. No.: US 2013/0256848 A1
(43) Pub. Date: Oct. 3, 2013

(54) ELECTRONIC COMPONENT MODULE AND METHOD OF MANUFACTURING THE SAME

(71) Applicant: TDK CORPORATION, Tokyo (JP)

(72) Inventors: Kenichi KAWABATA, Tokyo (JP); Seiko KOMATSU, Tokyo (JP)

(73) Assignee: TDK CORPORATION, Tokyo (JP)

(21) Appl. No.: 13/852,218

(22) Filed: Mar. 28, 2013

(30) Foreign Application Priority Data
Mar. 29, 2012 (JP) 2012-077034

(51) Int. Cl. H01L 23/60

(52) U.S. Cl. CPC H01L 23/60
USPC 257/659; 438/124

(57) ABSTRACT

An electromagnetic component module includes: a molding resin provided so as to cover electronic components mounted on a substrate and a surface of the substrate; and a conductive shield formed so as to further cover the molding resin. The conductive shield includes a first filler and a second filler which are different from each other and the conductive shield is connected to ground wires exposed on lateral surfaces of the substrate. The average particle diameter of the first filler is ½ or less of the thickness of the ground wires and the second filler forms a metallic bond in the temperature range of 250 degrees Celsius or lower.

### CROSS-REFERENCES TO RELATED APPLICATIONS

This application relates to and claims priority from Japanese Patent Application No. 2012-077034, filed on Mar. 29, 2012, the entire disclosure of which is incorporated herein by reference.

### BACKGROUND

1. Field of the Invention

The invention relates to an electronic component module and method of manufacturing the same.

2. Description of Related Art

An electronic component module has electronic components used for electronic equipment, including active components such as semiconductor devices (e.g., IC chips), and passive components such as capacitors, inductors (coils), thermistors and resistors, in such a manner that they are mounted on a single substrate. Of such electronic component modules, an electronic component module covered with a metallic casing or housed in a metallic casing and an electronic component module in which electronic components are covered with a molding resin and then an electromagnetic shielding layer is formed on the surface of the molding resin by metal plating, in order to provide protection from electromagnetic noise from the outside and/or to prevent electromagnetic noise from leaking out from the module itself, have been conventionally known.

In recent years, there have been increasing needs for further reduction in the size and thickness of electronic equipment and for higher-density packaging. While such needs exist, the above-mentioned electronic component module having a metallic casing as electromagnetic shielding cannot secure a sufficient height for the side walls of the substrate and thus the metallic casing cannot be joined with the substrate at the side walls thereof, and such electronic component module then has to have a structure in which a plate-shaped metallic casing is mounted on the module having a land on a substrate surface and in which the land and the metallic casing are joined with each other using solder or the like. This structure leaves the land portion as a dead space and cannot allow any electronic component to be mounted thereon or any wiring layer to be provided therein and thus such structure is not preferable in terms of size reduction and high-density packaging.

In addition, since the electronic component module having the electromagnetic shielding layer formed by metal plating on the molding resin uses, in many cases, various types of chemical solutions for plating, the substrate and/or electronic components may be damaged. Furthermore, the plating process requires a relatively long time and the scale of the device becomes relatively large, the productivity will disadvantageously be lowered. In addition, a molding resin typically used in transfer molding sometimes contains about 90 mass % of filler (e.g., molten silica) and the adhesion strength (bonding strength) between the filler in the molding resin and the metal plate is small, which may cause problems such as delamination of the metal plate and a decrease in yield.

Under such circumstances, for example, Patent Document 1 describes an electronic component module which is formed by connecting electrodes on a wiring substrate having a wiring layer to circuit components through the use of solder or conductive adhesive, forming a conductive foil on a surface layer (top surface) of an insulating resin covering the same, and electrically connecting the conductive foil to a ground pattern (ground wire) on the wiring substrate via a conductive substance provided on lateral surfaces of the insulating resin to thereby form an electromagnetic shielding layer. Patent Document 1 describes, as an example of the conductive substance used for the electromagnetic shielding layer, a conductive resin composition obtained by mixing metal particles and a thermosetting resin, in which examples of the metal particles include Au, Ag and Cu.
Patent Document 1: JP2005-159227 A

However, the inventors of the present invention, after having devoted themselves to study of the electromagnetic noise shielding performance of the electromagnetic shielding layer and the connection reliability between the electromagnetic shielding layer and the ground pattern on the substrate, etc. of the related-art electronic component module described in Patent Document 1, found that the electromagnetic noise shielding performance and the connection reliability were still insufficient.

In particular, electronic component modules for, for example, mobile terminal equipment in recent years are required to be kept short so that the total heights thereof are, for example, 1.5 mm or less, or even 1 mm or less. Due to such requirement, the thickness of a substrate on which electronic components are to be mounted has to be thinner than 0.5 mm (in this case, the thickness of a wiring layer of the substrate will be, for example, several tens of micrometers). However, the configuration of the related art electromagnetic shielding layer makes it difficult to securely connect the ground pattern exposed on the lateral surfaces of the substrate and the electromagnetic shielding layer and thus the above requirement for the electronic component module cannot be sufficiently satisfied.

### SUMMARY

The present invention has been made under such circumstances and it is an object of the present invention to provide an electronic component module and a method of manufacturing the same which are capable of contributing to a further reduction in height and improving the electromagnetic noise shielding performance (electromagnetic shielding properties) of an electromagnetic shield as well as the connection reliability between the electromagnetic shield and wires such as a ground pattern, as compared to the related art.

In order to achieve the object set forth above, an electronic component module according to the present invention includes: a substrate; an electronic component mounted on a surface of the substrate; a molding resin provided so as to cover the surface of the substrate and the electronic component; and a conductive shield provided so as to cover the molding resin, in which: the conductive shield includes a first filler and a second filler whose characteristics, physical properties, etc. are different from each other and the conductive shield is connected to a ground wire (a wire, a wiring pattern, a ground pattern, etc. connected to a ground potential) exposed on a lateral surface of the substrate; an average particle diameter of the first filler is ½ or less, preferably ⅓ or less, of a thickness of the ground wire; and the second filler forms a metallic bond in a temperature range of 250 degrees Celsius or lower.

In the electronic component module having the above configuration, the conductive shield is provided so as to cover the molding resin in which the electronic component mounted on the substrate surface is embedded, and the conductive shield is connected to the ground wires exposed on the lateral surface of the substrate to thereby function as a shielding body against electromagnetic noise.

In general, in the related art electronic component module having the electromagnetic shield formed from a conductive resin composition containing the metal particles (filler) described in Patent Document 1, etc., a conductive passage (conductive path) is formed only by physical contact between the metal particles contained in the electromagnetic shield. On the other hand, in the electronic component module of the present invention, the conductive shield includes a first filler and a second filler having, for example, materials and particle diameters (particle diameter distributions or particle size distributions) different from each other, and conductive passages is formed not only by the physical contact between these fillers but also by the metallic bond formed by the second filler in the temperature range of 250 degrees Celsius or lower.

In other words, during the formation of the conductive shield, when a precursor thereof (e.g., a conductive paste for forming the conductive shield) is heated to a predetermined temperature, the second filler is melted or the surface of the second filler is activated, a metallic bond occurs between particles in the second filler to cause them to join with one another, and furthermore, the first filler and second filler, as well as the second filler and ground wires, are also joined by the metallic bond. As a result, the denseness of the conductive shield is enhanced and the mechanical strength and electrical connection reliability of the conductive shield itself and between the conductive shield and ground wires are improved.

As a result of detailed studies, the inventors have found that, when the average particle diameter of the first filler is ½ or less of the thickness of the ground wires, the electromagnetic noise shielding performance (shielding properties) of the electromagnetic shield and the connection reliability between the electromagnetic shield and the ground wires can further be improved as compared to the related art.

In addition, it may be preferable that: the conductive shield contains a thermosetting or thermoplastic resin or resin composition; and the second filler forms the metallic bond in a temperature range of lower than a curing temperature of the resin or the resin composition.

Typically, when an uncured resin is heated, the viscosity of the resin is temporarily lowered (softened) in accordance with the increase in temperature, and then when the curing reaction of the resin starts, the viscosity of the resin increases gradually and finally the entire resin becomes cured. At this time, if the second filler forms a metallic bond in the temperature range below the curing temperature of the resin or the resin composition, the particles in the second filler, the first filler and second filler and the second filler and ground wires are joined with one another due to the metallic bond before the resin is cured, and this joining state is maintained rigidly by the curing of the resin, resulting in further improvements in the mechanical strength and electrical connection reliability of the conductive shield itself and between the conductive shield and the ground wires.

Specifically, the first filler may mainly contain at least one type of metal selected from Ag, Cu and Ni; and the second filler may mainly contain at least one type of metal selected from Sn, Ag, Cu, Au, Bi, In, Zn and Sb.

More specifically, examples of the second filler may include a nanofiller and a metal filler which melts at a low temperature. A material of the nanofiller may be at least one type selected from Ag, Cu and Au, in which Ag is particularly preferable in terms of economic efficiency and corrosion and oxidation resistance properties. A material of the metal filler which melts at a low temperature may be at least one type selected from Sn, Ag, Cu, Bi, In, Zn and Sb, in which a more preferable metallic filer contains Sn as the main material (main ingredient) and at least one type selected from Ag, Cu, Bi, In, Zn and Sb.

It may be preferable the content of the first filler and the second filler in the conductive shield, i.e., the total content of these fillers in the entire conductive shield, is from 50 to 95 mass %

A method of manufacturing an electronic component module according to the present invention is a method for effectively manufacturing the above-mentioned electronic component module according to the present invention, the method including the steps of: preparing a substrate: mounting an electronic component on a surface of the substrate; providing a molding resin so as to cover the surface of the substrate and the electronic component; and providing a conductive shield so as to cover the molding resin, in which the step of providing the conductive shield includes using, as the conductive shield, a first filler and a second filler which are different from each other and connecting the conductive shield to a ground wire exposed on a lateral surface of the substrate, in which: an average particle diameter of the first filler is ½ or less of a thickness of the ground wire; and the second filler forms a metallic bond in a temperature range of 250 degrees Celsius or lower

When the first filler and second filer formed from specific materials are used in terms of conductivity, economic efficiency and melting properties at a low temperature, some materials may cause, due to the corrosion (oxidation) thereof, disadvantages in which proper joining cannot be formed by the metallic bond or a conduction resistance (volume resistance value) is excessively increased. Although the addition of a reducing agent (antioxidant) to the conductive paste, etc. for forming the conductive shield is effective in order to prevent such disadvantages, the addition of an excess amount of such reducing agent may cause another problem in which a metal other than the filler, being the target of preventing the generation of an oxide film and removing an oxide film, may become corroded more easily or the storage stability of the conductive paste may be deteriorated.

Under such circumstances, it may be preferable to use, in the step of providing the conductive shield, the first filler consisting of Cu or mainly containing Cu and the second filler consisting of a metal which is easier to become corroded (easier to be oxidized) than Ag or mainly containing the metal which is easier to become corroded than Ag and to configure the step of providing the conductive shield so as to include the step of applying the conductive paste including such first filler and second filler onto the molding resin and the step of heating and curing the applied conductive paste in ambient air with a reduced oxygen concentration relative to the oxygen concentration under the atmospheric pressure (to thereby form the conductive shield).

More specifically, in the step of providing the conductive shield, a preferable example of the second filler may be a filler consisting of Sn and Bi or a filler mainly containing Sn and Bi.

In the step of heating and curing the conductive paste, the oxygen concentration may preferably be 30% or less of the oxygen concentration under the atmospheric pressure.

In the step of providing the conductive shield, the conductive paste may be configured so as to contain 5 mass % or less of reducing agent on the basis of the mass of the second fillers.

In the step of heating and curing the conductive paste, the ambient air with a reduced oxygen concentration may be formed by substituting at least part of the surrounding air of the conductive paste with an inert gas or a reducing gas or by reducing the pressure of the surrounding air of the conductive paste.

### EFFECT OF THE INVENTION

In the electronic component module according to the present invention, the conductive shield, provided so as to further cover the molding resin which covers the surface of the substrate and the electronic components and so as to be connected to the ground wires exposed on the lateral surfaces of the substrate, includes the first filler and the second filler, the average particle diameter of the first filler being ½ or less of the thickness of the ground wires, the second filler forming a metallic bond in the temperature range of 250 degrees Celsius or lower. Thus, the electronic component module according to the present invention can significantly improve the electromagnetic noise shielding performance (shielding properties) and the mechanical strength and electrical connection reliability of the conductive shield (electromagnetic shield) itself and between the conductive shield and the ground wires as compared to the related art.

In addition, in using the first filler consisting of Cu or mainly containing Cu and the second filler consisting of a metal which is easier to become corroded than Ag or mainly containing the metal which is easier to become corroded than Ag, by heating and curing the conductive paste, which contains such filers and which is applied onto the molding resin, in the ambient air with a reduced oxygen concentration relative to the oxygen concentration under the atmospheric pressure, the first filler, second filler and ground wires can be properly joined by the respective metallic bonds, which allows for the suppression of an excessive increase in the conduction resistance (volume resistance value) and a reduction in the amount of reducing agent to be added to the conductive paste, etc. for forming the conductive shield to thereby achieve improvements in the corrosion resistance of Cu and in the storage stability of the conductive paste.

### BRIEF DESCRIPTION OF THE DRAWINGS

FIGS. 1A to 1D are process flow diagrams (partial cross-sectional views) showing the states of an electronic component module according to the present invention being manufactured in accordance with a preferable embodiment of a method of manufacturing an electronic component module according to the present invention.

FIGS. 2A to 2C are process flow diagrams (partial cross-sectional views) showing the states of an electronic component module according to the present invention being manufactured in accordance with a preferable embodiment of a method of manufacturing an electronic component module according to the present invention.

FIG. 3 is a partial cross-sectional view showing a preferable embodiment of an electronic component module according to the present invention.

FIG. 4 is an electron micrograph showing, in an enlarged view, the cross section of a conductive shield in an electronic component module of Comparative Example 1.

FIGS. 5A and 5B are electron micrographs showing, in enlarged views, the cross sections of conductive shields in electronic component modules of Example 1 and Example 2, respectively.

FIG. 6 is a graph showing the result of an evaluation of shield properties for power management modules of Comparative Example 2, Example 4, a blank sample and a reference sample based on a near magnetic field test.

### DETAILED DESCRIPTION OF PREFERRED EMBODIMENTS

Embodiments of the present invention will be described in detail below. Note that positional relationships, such as top, bottom, right and left, are based on the positional relationships shown in the drawings unless otherwise indicated. In addition, dimensional ratios in the drawings are not limited to those shown. The embodiments below are merely examples for describing the present invention and are not intended to limit the present invention to those embodiments. Various modifications may be made to the present invention without departing from the gist of the invention.

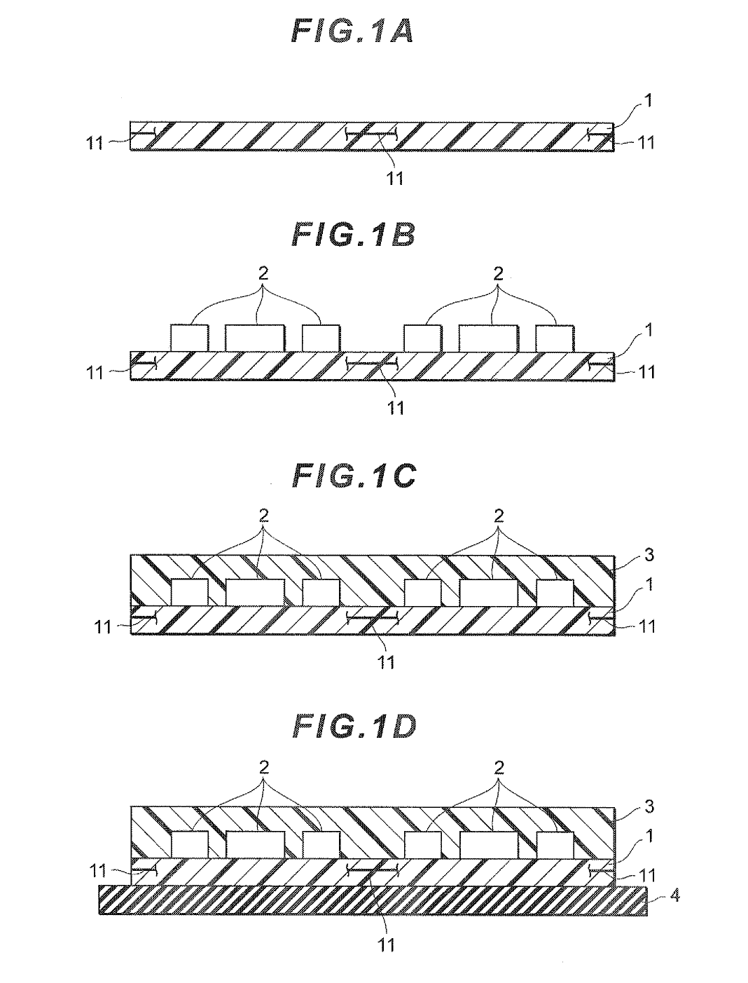

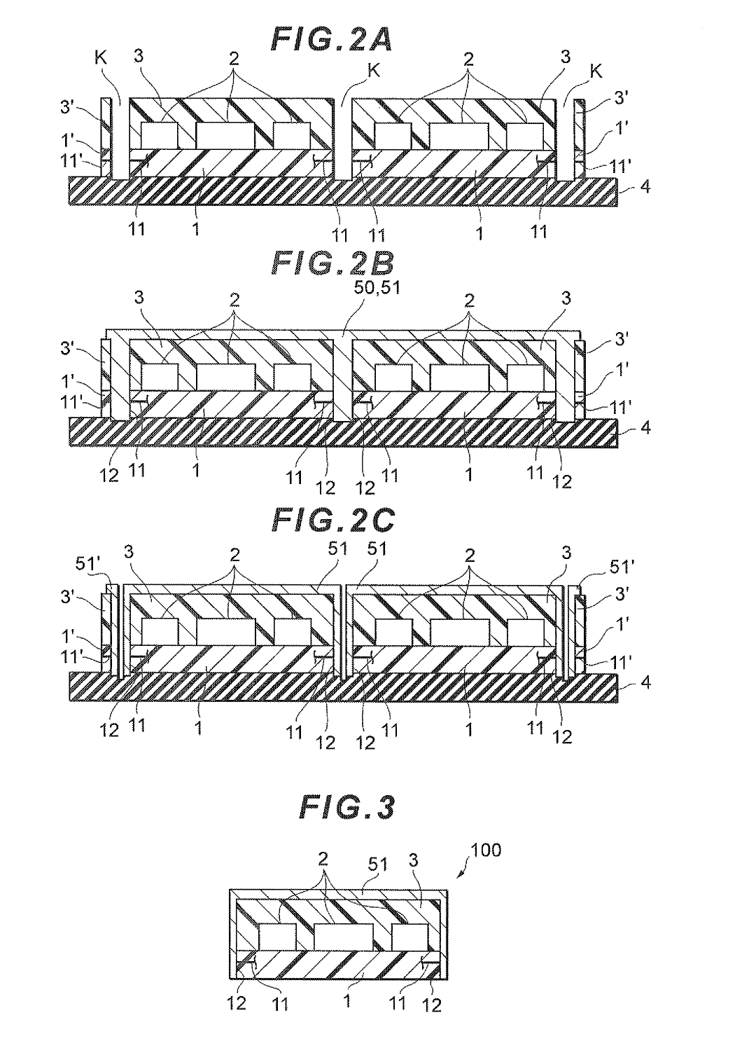

FIGS. 1A to 1D and 2A to 2C are process flow diagrams (partial cross-sectional views) showing the states of an electronic component module according to the present invention being manufactured in accordance with a preferable embodiment of a method of manufacturing the electronic component module according to the present invention, and specifically show an example of processes in which an integrated substrate incorporating a plurality of electronic components is prepared as a working board and then individual products (individual pieces) of electronic component modules are obtained. FIG. 3 is a partial cross-sectional view showing a preferable embodiment of the resulting electronic component module of the present invention.

First, a working board obtained by adhering a metal film such as a Cu foil to a single side or both sides of an insulating layer formed from, for example, glass epoxy, i.e., a single-sided or double-sided CCL (Copper Clad Laminate) is prepared. After forming vias in the working board by drilling and laser punching and subjecting the working board to electrolytic plating and non-electrolytic plating, patterning is provided to the metal layer using known methods. Then, for example, a resin sheet is formed on at least one surface by a known method such as vacuum press and vacuum lamination, vias are further formed therein, electrolytic plating and non-electrolytic plating are performed and then the patterning is provided. By repeating these steps, a substrate 1 with further insulating layers formed on wiring layers is obtained (FIG. 1A: Step of preparing a substrate). As described above, the substrate 1 has a multilayer structure.

A part of the patterns on the wiring layers in the substrate 1 functions as ground wires 11 (ground pattern) and a part of the ground wires 11 is shown in FIGS. 1A to 1D and FIGS. 2A to 2C. Materials of the ground wires 11 are not particularly limited, and examples of such materials may include, in addition to the above-mentioned Cu, conductive metal materials such as Au, Ag, Ni, Pd, Sn, Cr, Al, W, Fe, Ti and SUS. Of these, Cu is preferable in terms of electrical conductivity and economic efficiency (the same applies to other wiring layers not shown in the drawings).

Any material may be used, without particular limitation, as the material of the insulating layers of the substrate 1, as long as such material can be formed into a sheet or a film. In addition, materials that can be processed into a paste for application or printing may also be sufficiently usable. Examples of such materials may include an appropriate resin material, a material obtained by adding various types of fillers, such as silica and metal oxide particles, to a resin, a material obtained by mixing fibers, etc. in a resin and a material obtained by impregnating a cloth or a nonwoven fabric with a resin, and a suitable material, in terms of electrical properties, mechanical properties, water-absorbing properties, reflow resistance, etc., may be selected for use. In addition, the substrate 1 may be a multilayer wiring substrate in which wiring layers and insulating layers are further laminated or may be, for example, a typical printed circuit board (PCB) or an LTCC (Low Temperature Co-fired Ceramic) substrate.

Next, the substrate 1 is provided with via conductors to be connected to wires therein and then predetermined wiring patterns, lands, etc. to be connected to the via conductors are provided on the surface of the substrate 1. Then, electronic components 2 are mounted on the surface of the substrate 1, and connected and fixed to the wires on the substrate 1 using solder, conductive adhesive or the like (FIG. 1B: Step of mounting an electronic component on the surface of the substrate). These electronic components are, for example, active components such as semiconductor ICs mounted as bare chips (bare chips: dies) and passive components such as a capacitor, an inductor (coil), a thermistor and a resistor, and one or more electronic components 2 are mounted at a predetermine position(s) for every product area of an individual product of the electronic component module.

On the substrate 1 having the electronic components 2 arranged horizontally, a molding resin 3 is provided so as to cover the surfaces of the electronic components 2 and substrate 1 (FIG. 1C: Step of providing a molding resin). The technique for forming the molding resin is not particularly limited and may be, for example, by way of transfer, compression, printing, lamination and casting. The substrate 1 provided with the molding resin 3 is fixed to a support 4 which may have, for example, a plate-like shape and which is provided for dicing (to be described later) by adhesion or the like (FIG. 1D).

Next, dicing (cutting) is performed in the X and Y directions of the substrate 1 at positions corresponding to respective product areas of the individual products of electronic component modules by using a dicing blade or the like (FIG. 2A). The dicing is performed so as to divide the molding resin 3 into the respective product areas of the individual products but not to cut the support 4 completely, so that slits K (deep grooves) reaching an upper layer of the support 4 are formed. As a result, ground wires 11 are exposed on lateral surfaces 12 of the substrate 1. Although the slits K are formed so as to cut the substrate 1 completely in this embodiment, the substrate 1 may not necessarily be cut completely. Instead, the slits K may be formed such that the dicing is performed to a depth which allows the ground wires 11 to be exposed on the lateral surfaces 12 of the substrate 1. Note that, in FIGS. 2A to 2C, the substrate 1, molding resin 3 and ground wires 11 separated from the product areas of the individual products as a result of the dicing are denoted by reference numerals 1′, 3′ and 11′, respectively. (The same applies to conductive shield 51 to be described later).

Next, internal spaces of the trench-like slits K formed by the dicing and a top surface (upper surface) of the molding resin 3 are filled with or coated with a conductive paste 50 containing a thermosetting or thermoplastic resin or resin composition, metal fillers, a solvent, an appropriate additive (such as a surface treating agent, a reducing agent (an oxidant), etc.), the conductive paste 50 is cured under predetermined heating conditions to form a conductive shield 51 (FIG. 2B: Step of providing a conductive shield including the step of applying a conductive paste on the molding resin and the step of heating and curing the conductive paste). Note that reference numerals 50 and 51 shown side by side in FIG. 2B indicate that the conductive shield 51 is formed from the conductive paste 50.

The metal fillers contained in the conductive paste 50 (which finally turns into the conductive shield 51) used in this embodiment include a first filler and a second filler whose characteristics and physical properties are different from each other. The first filler, which is sometimes referred to as a base filler, has an average particle diameter (volume median diameter as converted into spheres: d50) of ½ or less, preferably ⅓ or less, of the thickness of the ground wire 11 and mainly contains at least one type of metal selected from Ag, Cu and Ni.

The second filler forms a metallic bond in the temperature range of 250 degrees Celsius of lower and mainly contains at least one type of metal selected from Sn, Ag, Cu, Bi, In, Zn and Sb. As the second filler, a so-called nanofiller (nanosized fine particle filler) and for a metal filler which melts at a low temperature may be preferably used. In this case, the material of the nanofiller may be at least one type selected from Ag, Cu and Au. Of these metals, Ag is particularly preferable in terms of economic efficiency and corrosion resistance. The material of the metal filler which melts at a low temperature may be at least one type selected from Sn, Ag, Cu, Bi, In, Zn and Sb, and may more preferably be a material containing Sn as a main ingredient and at least one type selected from Ag, Cu, Bi, In, Zn and Sb.

It is preferable to adjust the content of the metal fillers (the content of the total amount of the first filler and second filler) contained in the conductive paste 50 so as to be from 50 to 95 mass % in the final conductive shield 51, although not particularly limited thereto. In addition, the mixing ratio between the first filler (base filler) and the second filler (nanofiller and/or metal filler which melts at a low temperature) in the conductive paste 50 is not particularly limited, either, and is preferably adjusted so that, for example, the ratio between the first filler and the second filler is in the range of from 95:5 to 30:70 (mass ratio) in the resulting conductive shield 51.

If the first filler consisting of Cu or mainly containing Cu and the second filler consisting of a metal which is easier to become corroded (oxidized) than Ag or mainly containing a metal which is easier to become corroded than Ag (e.g., those consisting of Sn and Bi or mainly containing Sn and Bi) are used in the step of providing the conductive shield shown in FIG. 2B in terms of electrical conductivity and economic efficiency, the conductive paste 50 applied on the molding resin 3 or provided to fill the internal spaces of the slits K are preferably heated and cured in ambient air with a reduced oxygen concentration relative to the oxygen concentration under the atmospheric pressure in the step of heating and curing the conductive paste.

With such configuration, the oxidation of the first filler and second filler can be suppressed effectively and the content of the required reducing agent can be reduced, e.g., the content of the reducing agent can be reduced to 5 mass % or lower relative to the mass of the second filler. Note that the type of reducing agent used herein is not particularly limited, and preferable examples of the reducing agent may include rosin materials represented by abietic acid, various types of amines or the salts thereof, organic acids having a carboxylic acid such as sebacic acid, stearic acid, oleic acid and levulinic acid. One of these materials may be used alone or two or more of them may be used in combination. In addition, in order to further suppress the corrosion (oxidation) of Cu used as the first filler, Cu particles may preferably be treated with formic acid or coated with Ag or an organic film.

Examples of technique for reducing the oxygen concentration of the ambient air surrounding the substrate 1 having the conductive paste 50 applied thereto or filled therein shown in FIG. 2B relative to the oxygen concentration under the atmospheric pressure may include substituting at least part of the ambient air surrounding the conductive paste 50, at least on the substrate 1, with an inert gas or a reducing gas and reducing the pressure of the ambient air surrounding the conductive paste 50 at least on the substrate 1. More specifically, it is more preferable that the oxygen concentration of the ambient air surrounding the substrate 1 having the conductive paste 50 applied thereto and filled therein shown in FIG. 2B is maintained (controlled or managed) at 30% or lower, and particularly preferably at 1.5% or lower, relative to the oxygen concentration under the atmospheric pressure.

As described above, after heating and curing the conductive paste 50 to form the conductive shield 51 as shown in FIG. 2B, the conductive shield 51 is diced at the positions of the slits K using, for example, a dicing blade having a smaller blade width than the dicing blade used for dicing in FIG. 2A, (FIG. 2C) and the substrate 1 in the state shown in FIG. 2C is removed from the support 4 to thereby obtain an electronic component module 100 being a preferable embodiment of the electronic component module according to the present invention shown in FIG. 3.

As shown in FIG. 3, the conductive shield 51 is formed so as to cover the top surface of the molding resin 3 in which the electronic components 2 are embedded and the lateral surfaces 12 of the molding resin 3 and the substrate 1 in the electronic component module 100, and the conductive shield 51 is connected to the ground wires 11 exposed on the lateral surfaces 12 of the substrate 1. As described above, the conductive shield 51 includes: the first filler (base filler) having the average particle diameter of ½ or less, preferably ⅓ or less, of the thickness of the ground wires 11; and the second filler (nanofiller or metal filler melting at a low temperature) which forms the metallic bond in the temperature range of 250 degrees Celsius or lower (lower than the curing temperature of the resin or resin composition contained in the conductive paste 50).

According to the electronic module 100 having such configuration and the method of manufacturing the same, first, the conductive shield 51 is provided so as to cover the molding resin 3 in which the electronic components 2 mounted on the surface of the substrate 1 are embedded, and the conductive shield 51 is connected to the ground wires 11 exposed on the lateral surfaces 12 of the substrate 1. Thus, the conductive shield 51 allows the electronic component module 100 to be shielded from outside electromagnetic noise and, in addition, suppress the electromagnetic noise which may be generated inside the electronic component module 100 from leaking outside.

Since the conductive paste 50 for forming the conductive shield 51 includes the second filler (nanofiller, metal filler which melts at a low temperature) which forms the metallic bond in the temperature range of 250 degrees Celsius or lower (lower than the curing temperature of the resin or resin composition contained in the conductive paste 50), by heating and curing the conductive paste 50, the conductive shield 51, which is denser than that seen in the related art, can be formed.

Specifically, when the conductive paste 50 is heated to a predetermined temperature, the second filler is melted (in the case of using the metal filler melting at a lower temperature) or the surface thereof is activated (in the case of using the nanofiller), and the particles in the second filler are joined with one another due to the formation of the metallic bond. In addition, the first filler and the second filler, as well as the second filler and the ground wires 11 are joined with one another, respectively, due to the metallic bond. As a result, the denseness of the conductive shield 51 is enhanced and the mechanical strength and electrical connection reliability of the conductive shield 51 itself and between the conductive shield 51 and the ground wires 11 can be improved.

More specifically, when the conductive paste 50 is heated, in accordance with the increase in the temperature thereof, a solvent component contained in the conductive paste 50 is volatilized and the viscosity of the resin contained in the conductive paste 50 is temporarily lowered (softened). Then, with the progress of the curing reaction of the resin, the viscosity of the resin increases gradually and finally the entire resin is cured. In this process, the second filler forms the metallic bond in the temperature range below the curing temperature of the resin or resin composition, the particles in the second filler, the first filler and second filler, and the second filler and ground wires 11 are joined with one another, respectively, due to the metallic bond, before the resin gets cured, and the curing of the resin causes the joining state to be rigidly maintained. Accordingly, the mechanical strength and electrical connection reliability of the conductive shield 51 itself and between the conductive shield 51 and the ground wires 11 can further be enhanced.

In other words, while a conductive passage is formed by the physical contact of the metal filler in an electromagnetic layer of the related art electronic component module, a far greater number of conductive passages (conductive paths) can be densely formed by the joints between the first filler, second filler and ground wires due to the metallic bond generated by the second filler in the electronic component module 100 as described above, and thus the mechanical strength and electrical connection reliability can be significantly enhanced. In addition, the conductivity stability can also be enhanced for the same reason.

In addition, since the ground wires 11 exposed on the lateral surfaces 12 of the substrate 1 and the conductive shield 51 are securely connected to one another as described above, this configuration can contribute to a further reduction in height (thickness) and thus a further reduction in the size of the electronic component module 100. Furthermore, since the conductive shield 51 having high denseness, rigidity and electromagnetic shielding properties can be achieved, the thickness of the conductive shield 51 on the molding resin 3 can further be thinned, leading to a further reduction in the height of the electronic component module 100.

In addition, since the range of thickness of the conductive shield 51 can thus be widened, it is possible to quite easily and efficiently form a conductive shield 51 having a suitable thickness depending on the electromagnetic shielding properties and frequencies required for various types of electronic component modules 100. As a result, the electronic component module 100 becomes applicable to a wide range of products, such as so-called power devices and RF devices, and it is also possible to increase productivity and reduce cost and to remarkably shorten lead time.

In addition, due to the achievement of excellent electromagnetic shielding properties and connection reliability as described above, the content of the metal fillers required for obtaining an electromagnetic shielding effect comparable to that seen in the related art can be reduced, and the cost of materials can further be reduced in such case. Furthermore, by thus reducing the content of the metal fillers in the conductive paste 50, the content of the resin in the conductive paste 50 can be increased, the adhesion properties between the conductive shield 51 and the molding resin 3 can also be enhanced.

Regarding the aspect of the second filler forming the metallic bond, if the second filler is the nanofiller, the smaller the particle diameter of the filler becomes, the smaller the activation energy with respect to the surface areas of the particles becomes, and thus the nanofiller can be easily sintered (can easily produce neck growth) even if not melted completely. For example, Ag (silver nanofiller) having a particle diameter of about 30-50 μm could be sintered at about 150 degrees Celsius. At this time, although oxidation of Ag may be of concern, Ag can prevent the oxidation thereof due to a self-purifying effect when it is heated to such temperature, and thus a reducing agent may not need to be added to the conductive paste 50 or the content of a reducing agent may be reduced in such case.

If the second filler is the metal filler which melts at a low temperature, e.g., in a situation where the second filler containing Sn as the main material (main ingredient) and at least one type selected from Ag, Cu, Bi, In, Zn and Sb is used, a desired melting temperature can be achieved by varying the mixing ratio therebetween. For example, low melting temperatures can be achieved by Sn alone having a melting temperature of about 232 degrees Celsius, a composition of or close to Sn—Ag eutectic having a melting temperature of about 220 degrees Celsius, an Sn—Bi based composition having a melting temperature of 180 degrees Celsius or lower and a composition of or close to Sn—Bi eutectic having a melting temperature of about 140 degrees Celsius, which are melted at temperatures sufficiently lower than the curing temperature of the resin contained in the conductive paste 50 and which produce the neck growth due to the rigid metallic bond. In addition, having a melting temperature of 180 degrees Celsius or lower could alleviate thermal influences on the substrate 1 (in particular, PCB) and the molding resin 3 when the conductive paste 50 is heated, which is advantageous in process management.

Although such Sn—Bi eutectic system metal fillers melted at low temperatures can achieve low melting temperatures, as described above, they may easily get oxidized as compared to Ag, etc., and thus a reducing agent is preferably added to such conductive paste 50. However, although an excessive increase in the amount of reducing agent to be added may be effective in preventing corrosion of the Sn—Bi eutectic system metal fillers melted at low temperatures or in removing produced oxide films, it will also cause disadvantages in which, for example, other metals, such as Cu used as the first filler (base filler) become corroded easily or the storage stability of the conductive paste 50 is deteriorated.

In this regard, by reducing the oxygen concentration in the ambient air surrounding the substrate 1 having the conductive paste 50 shown in FIG. 2B applied thereto and filled therein relative to the oxygen concentration under the atmospheric pressure (i.e., adjusting the oxygen concentration of the surrounding ambient air or the surrounding environment so as to be lowered) as described above in this embodiment, the oxidation of the Sn—Bi eutectic system metal filler, being the second filler, which melts at a low temperature can be sufficiently suppressed. With such configuration, degradation of electrical properties, such as an increase in conduction resistance (volume resistance value) of the conductive shield 51 formed from the conductive paste 50 due to oxides, can be prevented, and the amount of reducing agent to be used can be reduced to thereby suppress the corrosion of Cu, etc. and the deterioration of the storage stability of the conductive paste 50.

### EXAMPLES

The present invention will be further described below with reference to Examples and Comparative Examples. It should be noted, however, that the present invention is not limited to these Examples.

### Comparative Example 1

A conductive paste (AE1244 manufactured by TATSUTA ELECTRIC WIRE & CABLE CO., LTD.) containing, as a metal filler, Cu-coated Ag powder having an average diameter of 6 μm, was used to prepare an electronic component module having the same configuration as the electronic component module 100 according to the present invention shown in FIG. 3.

### Example 1

A conductive paste was prepared using flat-shaped Ag powder having an average particle diameter of 5 μm as the first filler (base filler), Ag nanofiller having an average particle diameter of 30 nm as the second filler, an epoxy resin (liquefied bisphenol A epoxy resin and imidazole) and butyl carbitol acetate. The total content of the first filler and second filler in this conductive paste was 90 mass % on the basis of the mass of the epoxy resin. The conductive paste was provided by stencil printing on the substrate 1 and molding resin 3, then heated and cured at 70 degrees Celsius for 30 minutes and at 160 degrees Celsius for 60 minutes to form a cured film of the conductive shield 51, to thereby prepare an electronic component module according to the present invention having the same configuration as the electronic component module 100 shown in FIG. 3.

### Example 2

An electronic component module according to the present invention was prepared in the same manner as in Example 1, except that Cu-coated Ag powder having an average particle diameter of 5 μm was used as the first filler and Sn—Bi spherical powder having an average particle diameter of 5 μm was used as the second filler. The total content of the first filler and second filler in this conductive paste was 90 mass % on the basis of the mass of the epoxy resin.

Test and Evaluation 1: Observation on Cross Sections of Conductive Shields (States of Neck Growth)

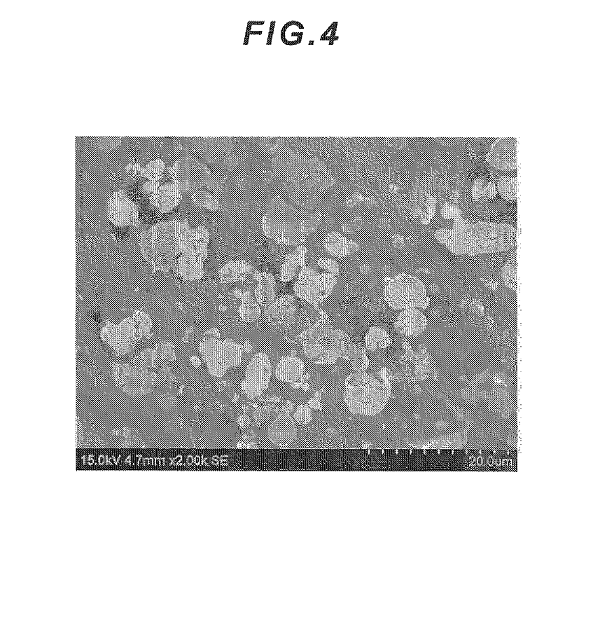

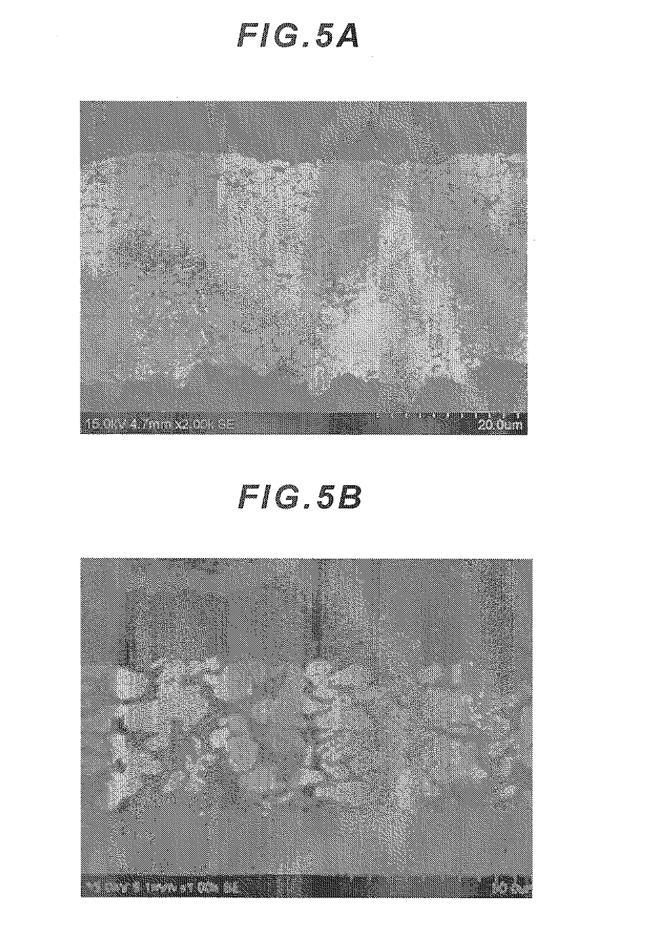

FIG. 4 and FIGS. 5A and 5B are electron micrographs showing, in enlarged views, the cross sections of conductive shields in the electronic component modules obtained in Comparative Example 1 and Examples 1 and 2, respectively. Note that one tick of the scale shown in the photos in FIG. 4 and FIGS. 5A and 5B corresponds to 20 μm. The result shown in FIG. 4 indicates that individual particles in the metal filler (individual circular regions having a relatively bright gray color in the photo) are merely in physical contact with one another in the conductive shield of the electronic component module in Comparative Example 1.

The result shown in FIG. 5A indicates the state in which the individual particles in the first filler and second filler cannot clearly be distinguished from one another in the conductive shield of the electronic component module in Example 1, where the first filler and second filler form the neck growth due to the metallic bond and they are joined substantially integrally with one another (the belt-like region having a relatively bright gray color and occupying the main part of the photo).

The result shown in FIG. 5B indicates the state in which the individual particles in the first filler and second filler cannot clearly be distinguished from one another also in the conductive shield of the electronic component module in Example 2, where more than one particle in the second filler and the first filler form the neck growth due to the metallic bond and the integrated bodies thereof (the noncircular region having a relatively bright gray color in the photo) are further joined and connected with one another by a metallic bond.

### Comparative Example 2 and Examples 3 and 4

Power management modules, being electronic component modules of Comparative Example 2 and Examples 3 and 4, were prepared using the conductive pastes prepared in Comparative Example 1 and Examples 1 and 2, respectively. The outer dimension of an individual module was 11 mm long and 11 mm wide. The production process included, in the same way as the production process for the above-mentioned embodiment, mounting electronic components on a substrate (integrated substrate), covering it with the molding resin, forming slits in the X and Y directions by dicing, applying the conductive paste to the top surface of the molding resin and the lateral surfaces of the molding resin and substrate by vacuum printing, heating and curing the conductive paste, and performing singulation.

Test and Evaluation 2: Electromagnetic Shielding Properties

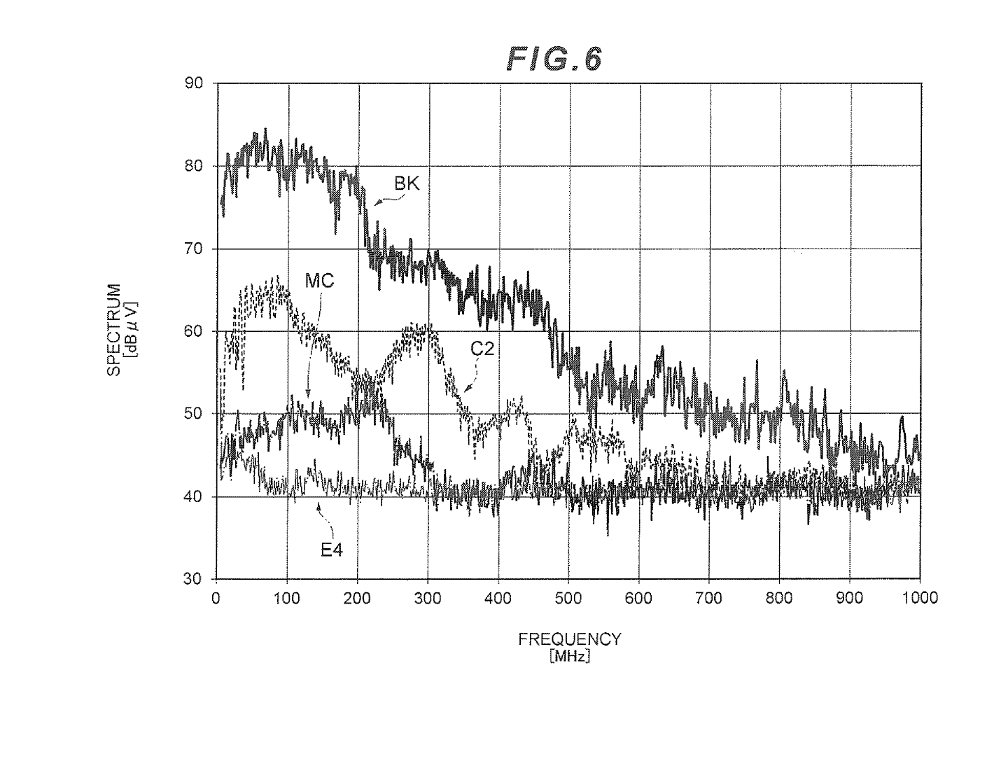

A near magnetic field test in the frequency range of 1-1000 MHz was conducted on the power management modules obtained in Comparative Example 2 and Examples 3 and 4. In addition, the same near magnetic field test was also conducted for a power management module (blank sample) prepared in the same way as Comparative Example 2 and Examples 3 and 4, except that it had no conductive shield, and for a power management module (reference sample) having a metallic casing shield instead of the conductive shield formed from the conductive paste. FIG. 6 is a graph showing the evaluation results based on the near magnetic field tests regarding the shielding properties of the power management modules in Comparative Example 2, Example 4, the blank sample and the reference sample.

These results indicate that the power management module in Example 4 (the chart indicated by arrow E4 in the graph) had far superior electromagnetic shielding properties (shielding performance) in a very wide frequency range of 1-1000 MHz as compared to the power management modules in the blank sample (the chart indicated by arrow BK in the graph) and in Comparative Example 2 (the chart indicated by arrow C2 in the graph). In addition, the results indicate that the power management module in Example 4 (the chart indicated by arrow E4 in the graph) also had far superior electromagnetic shielding properties (shielding performance) in, in particular, a wide frequency range of 1-300 MHz as compared to the power management module in the reference sample (the chart indicated by arrow MC in the graph).

### Comparative Example 3 and Examples 5 and 6

Electronic component modules of Comparative Example 3 and Examples 5 and 6 were prepared using the conductive pastes prepared in Comparative Example 2 and Examples 3 and 4 basically in the same way as in Comparative Example 2 and Examples 3 and 4, except that a substrate (integrated substrate) having four layers of wiring conductors (corresponding to the ground wire layers) with different thicknesses was used.

The thickness of the substrate was 0.3 mm and the thicknesses of the four layers of wiring conductors provided on the substrate were 12 μm, 18 μm, 25 μm and 35 μm, respectively. The molding resin (thickness: 0.5 mm) was formed by using transfer molding, and slits having a width of 0.4 mm were formed by dicing to thereby expose the four layers of wiring conductors on the lateral surfaces of the substrate. The conductive paste was applied by vacuum printing (thickness of stencil: 50 μm). The thickness of the conductive paste on the top surface of the molding resin was 20-30 μm.

Test and Evaluation 3: Observation on Cross-Sections of Connecting Part between Conductive Shield and Wiring Conductors (Connection Reliability)

The cross section of the conductive shield and the four layers of wiring conductors in the electronic component module obtained in each of Comparative Example 3 and Examples 5 and 6 was observed in an enlarged view using an electron micrograph. The evaluation results of each connection state between the conductive shield and wiring conductors are shown in Table 1. In Table 1, “A” indicates preferable connection, “B” indicates insufficient connection and “C” indicates poor connection.

TABLE 1

| | Thickness of Wiring Conductors | | | |
|---|---|---|---|---|
| | 12 μm | 18 μm | 25 μm | 35 μm |
| Comparative Example 3 | C | C | B | A |
| Example 5 | A | A | A | A |
| Example 6 | A | A | A | A |

These results indicate that the electronic component module in Comparative Example 3 could not achieve secure connection between the conductive shield and the wiring conductors unless the wiring conductor has a thickness of 35 μm or more, while the electronic component modules in Examples 5 and 6 were able to achieve preferable connection between the conductive shield and wiring conductors even with the very thin wiring conductor of about 10 μm in thickness (in these Examples, the average particle diameter of the first filler was 5 μm which is ½ of the thickness of the wiring conductor corresponding to the ground wires).

Although the connection with the thin wiring conductors in the electronic component module of the Comparative Example was tried to be improved by employing flat-shaped and finer powder as the metal filler and extremely increasing the content of the metal filler, the BET value of the metal filler became excessively high and it became difficult to obtain a paste form. In addition, during such attempt, some disadvantages were found to occur in which a large amount of solvent was required and thus it took a long drying time in order to remove the solvent from the conductive paste filling the slits formed by dicing and a significant number of voids were generated.

### Comparative Example 4

An electronic component module having the same configuration as the electronic component module 100 according to the present invention shown in FIG. 3 was prepared using a conductive paste (AE3030 manufactured by TATSUTA ELECTRIC WIRE & CABLE CO., LTD.) containing Ag-coated Cu powder having an average particle diameter of 6 μm.

### Example 7

An electronic component module according to the preset invention was prepared in the same way as Example 1 except that: Cu-coated Ag flat-shaped powder having an average particle diameter of 5 μm was used as the first filler; Sn—Bi spherical powder having an average particle diameter of 5 μm was used as the second filler, butyl carbitol acetate and carboxylic acid were used; the conducive paste was heated under the conditions of 150 degrees Celsius for 20 minutes and 180 degrees Celsius for 60 minutes; and the oxygen concentration of the ambient air during the heating and curing process of the conductive paste was controlled to 500 ppm or less.

Test and Evaluation 4: Observation on Cross Section of Conductive Shield (State of Neck Growth)

The cross sections of the conductive shields in the electronic component modules obtained in Comparative Example 4 and Example 7 were observed in enlarged views using an electron microscope in the same way as in Test and Evaluation 1. The result indicates that individual particles of the metal filler (individual circular regions having a relatively bright gray color in the photo) were merely in physical contact with one another in the conductive shield of the electronic component module in Comparative Example 4, as in Comparative Example 1 described above. On the other hand, the result indicates the state in which the individual particles in the first filler and second filler cannot clearly be distinguished from each other in the conductive shield of the electronic component module in Example 7, where more than one particle in the second filler and the first filler form the neck growth due to the metallic bond and the integrated bodies thereof are further joined and connected with one another by a metallic bond, as in Example 2 described above.

Note that, as discussed above, the present invention is not limited to the embodiment above and various modifications may be made without departing from the gist of the present invention.

### INDUSTRIAL APPLICABILITY

As described above, the electronic component module and the method of manufacturing the same according to the present invention can improve the electromagnetic noise shielding performance (electromagnetic shielding properties) of an electromagnetic shield and the connection reliability between the electromagnetic shield and wires, such as a ground pattern, to be connected to the electromagnetic shield, even in the situation where the height and thickness of a substrate are further reduced. Thus, the present invention is widely and effectively applicable to equipment, apparatuses, systems, various types of devices, etc. having electronic components incorporated therein, for which, in particular, reduction in size and improvements in performance are required (e.g., small mobile terminal equipment), as well as to the manufacture thereof.

### EXPLANATION OF REFERENCE SYMBOLS

1, 1′: substrate
2: electronic component
3, 3′: molding resin
4: support
11, 11′: ground wire
12: lateral surface
50: conductive paste
51, 51′: conductive shield
100: electronic component module
K: slit

What is claimed is:

1. An electronic component module, comprising:
a substrate;
an electronic component mounted on a surface of the substrate;
a molding resin provided so as to cover the surface of the substrate and the electronic component; and
a conductive shield provided so as to cover the molding resin, wherein:
the conductive shield includes a first filler and a second filler which are different from each other and the conductive shield is connected to a ground wire exposed on a lateral surface of the substrate;
an average particle diameter of the first filler is ½ or less of a thickness of the ground wire; and
the second filler forms a metallic bond in a temperature range of 250 degrees Celsius or lower.

2. The electronic component module according to claim 1, wherein:
the conductive shield contains a resin or a resin composition; and
the second filler forms the metallic bond in a temperature range of lower than a curing temperature of the resin or the resin composition.

3. The electronic component module according to claim 1, wherein:
the first filler mainly contains at least one type of metal selected from Ag, Cu and Ni; and
the second filler mainly contains at least one type of metal selected from Sn, Ag, Cu, Bi, In, Zn and Sb.

4. The electronic component module according to claim 2, wherein:
the first filler mainly contains at least one type of metal selected from Ag, Cu and Ni; and
the second filler mainly contains at least one type of metal selected from Sn, Ag, Cu, Bi, In, Zn and Sb.

5. The electronic component module according to claim 1, wherein the second filler is a nanofiller or a metal filler which melts at a low temperature.

6. The electronic component module according to claim 2, wherein the second filler is a nanofiller or a metal filler which melts at a low temperature.

7. The electronic component module according to claim 3, wherein the second filler is a nanofiller or a metal filler which melts at a low temperature.

8. The electronic component module according to claim 1, wherein the content of the first filler and the second filler in the conductive shield is from 50 to 95 mass %.

9. The electronic component module according to claim 2, wherein the content of the first filler and the second filler in the conductive shield is from 50 to 95 mass %.

10. The electronic component module according to claim 3, wherein the content of the first filler and the second filler in the conductive shield is from 50 to 95 mass %.

11. The electronic component module according to claim 5, wherein the content of the first filler and the second filler in the conductive shield is from 50 to 95 mass %.

12. A method of manufacturing an electronic component module, the method comprising the steps of:
preparing a substrate:
mounting an electronic component on a surface of the substrate;
providing a molding resin so as to cover the surface of the substrate and the electronic component; and
providing a conductive shield so as to cover the molding resin, wherein the step of providing the conductive shield includes using, as the conductive shield, a first filler and a second filler which are different from each other and connecting the conductive shield to a ground wire exposed on a lateral surface of the substrate, wherein:
an average particle diameter of the first filler is ½ or less of a thickness of the ground wire; and
the second filler forms a metallic bond in a temperature range of 250 degrees Celsius or lower.
